(19) United States
(12) Patent Application Publication
(10) Pub. No.: US 2023/0380207 A1
(43) Pub. Date: Nov. 23, 2023

(54) DISPLAY DEVICE

(71) Applicant: Japan Display Inc., Tokyo (JP)

(72) Inventors: Jun NITTA, Tokyo (JP); Masakazu GUNJI, Tokyo (JP); Shinya ASAKURA, Tokyo (JP)

(73) Assignee: Japan Display Inc., Tokyo (JP)

(21) Appl. No.: 18/366,681

(22) Filed: Aug. 8, 2023

Related U.S. Application Data
(63) Continuation of application No. PCT/JP2022/000571, filed on Jan. 11, 2022.

(30) Foreign Application Priority Data
Feb. 9, 2021 (JP) 2021-018997

(51) Int. Cl. H10K 50/18; H10K 50/16; H10K 50/17; H10K 50/84; H10K 59/131

(52) U.S. Cl. CPC H10K 50/181; H10K 50/16; H10K 50/171; H10K 50/841; H10K 59/131

(57) ABSTRACT

According to one embodiment, a display device includes a switching element, a first insulating layer including a first contact hole penetrating to the switching element, a conductive material filled in the first contact hole, a lower electrode arranged above the first insulating layer and being in contact with the conductive material, an organic layer stacked on the lower electrode, and including a hole injection layer on the lower electrode, a hole transport layer on the hole injection layer, and a light emitting layer on the hole transport layer, an upper electrode stacked on the organic layer, and a coating layer covering an end surface of each of the lower electrode, the hole injection layer, and the hole transport layer.

### CROSS-REFERENCE TO RELATED APPLICATIONS

This application is a Continuation Application of PCT Application No. PCT/JP2022/000571, filed Jan. 11, 2022 and based upon and claiming the benefit of priority from Japanese Patent Application No. 2021-018997, filed Feb. 9, 2021, the entire contents of all of which are incorporated herein by reference.

### FIELD

Embodiments described herein relate generally to a display device.

### BACKGROUND

Recently, display devices with organic light-emitting diodes (OLEDs) applied thereto as display elements have been put into practical use. Such a display element comprises an organic layer between a pixel electrode and a common electrode. The organic layer includes functional layers such as a hole transport layer and an electron transport layer in addition to a light emitting layer. Increasing the area that contributes to display (light emission) in such a display element is requested.

### BRIEF DESCRIPTION OF THE DRAWINGS

FIG. 1 is a view showing a configuration example of a display device DSP according to the embodiments.

FIG. 2 is a view showing an example of a configuration of the display element 20.

FIG. 3 is a cross-sectional view showing a basic structure of the display device DSP.

FIG. 4 is a cross-sectional view showing a first structural example of the display device DSP.

FIG. 5 is a cross-sectional view showing a second structural example of the display device DSP.

FIG. 6 is a cross-sectional view showing a first example of the display element 20.

FIG. 7 is a cross-sectional view showing a second example of the display element 20.

FIG. 8 is a cross-sectional view showing a third example of the display element 20.

FIG. 9 is a cross-sectional view showing a fourth example of the display element 20.

FIG. 10 is a cross-sectional view showing a fifth example of the display element 20.

FIG. 11 is a cross-sectional view showing a sixth example of the display element 20.

FIG. 12A is a cross-sectional view showing a third structural example of the display device DSP.

FIG. 12B is a cross-sectional view showing a fourth structural example of the display device DSP.

FIG. 13A is a cross-sectional view showing a fifth structural example of the display device DSP.

FIG. 13B is a cross-sectional view showing a sixth structural example of the display device DSP.

FIG. 14A is a cross-sectional view showing a seventh structural example of the display device DSP.

FIG. 14B is a cross-sectional view showing an eighth structural example of the display device DSP.

FIG. 15A is a cross-sectional view showing a ninth structural example of the display device DSP.

FIG. 15B is a cross-sectional view showing a tenth structural example of the display device DSP.

FIG. 16 is a cross-sectional view showing a seventh example of the display element 20.

FIG. 17 is a cross-sectional view showing an eighth example of the display element 20.

FIG. 18 is a cross-sectional view showing a ninth example of the display element 20.

FIG. 19 is a cross-sectional view showing a tenth example of the display element 20.

FIG. 20 is a cross-sectional view showing an eleventh example of the display element 20.

FIG. 21 is a cross-sectional view showing a twelfth example of the display element 20.

FIG. 22 is a cross-sectional view showing a thirteenth example of the display element 20.

FIG. 23 is a cross-sectional view showing a fourteenth example of the display element 20.

FIG. 24 is a cross-sectional view showing a fifteenth example of the display element 20.

FIG. 25 is a schematic plan view showing the display element 20.

FIG. 26 is a cross-sectional view illustrating an example of a boundary surface BR between the conductive material CD and the lower electrode E1.

FIG. 27 is a cross-sectional view illustrating another example of the boundary surface BR between the conductive material CD and the lower electrode E1.

FIG. 28 is a plan view showing a configuration example of the upper electrodes E2.

FIG. 29 is a plan view showing another configuration example of the upper electrodes E2.

FIG. 30A is a plan view showing yet another configuration example of the upper electrode E2.

FIG. 30B is a plan view showing yet another configuration example of the upper electrodes E2.

FIG. 31A is a plan view showing yet another configuration example of the upper electrode E2.

FIG. 31B is a plan view showing yet another configuration example of the upper electrodes E2.

FIG. 32 is a plan view showing an embodiment.

FIG. 33 is a cross-sectional view showing the display element 20 shown in FIG. 32 along line A-B.

### DETAILED DESCRIPTION

Embodiments described herein aim to provide a display device capable of increasing an area contributing to display.

In general, according to one embodiment, a display device comprises a substrate, a switching element arranged above the substrate, a first insulating layer arranged above the substrate and including a first contact hole penetrating to the switching element, a conductive material filled in the first contact hole, a lower electrode arranged above the first insulating layer and being in contact with the conductive material, an organic layer stacked on the lower electrode and including a hole injection layer on the lower electrode, a hole transport layer on the hole injection layer, and a light emitting layer on the hole transport layer, an upper electrode stacked on the organic layer, and a coating layer covering an end surface of each of the lower electrode, the hole injection layer, and the hole transport layer.

According to another embodiment, a display device comprises a substrate, a switching element arranged above the substrate, a first insulating layer arranged above the substrate and including a first contact hole penetrating to the switching element, a conductive material filled in the first contact hole, a lower electrode arranged above the first insulating layer and being in contact with the conductive material, an organic layer including a light emitting layer, and stacked on the lower electrode, an upper electrode stacked on the organic layer, and a coating layer covering an end surface of the lower electrode.

According to yet another embodiment, a display device comprises a substrate, a switching element arranged above the substrate, a first insulating layer arranged above the substrate and including a first contact hole penetrating to the switching element, a conductive material filled in the first contact hole, a lower electrode arranged above the first insulating layer and being in contact with the conductive material, an organic layer including a light emitting layer, stacked on the lower electrode, and covering an end surface of the lower electrode, and an upper electrode stacked on the organic layer and covering an end surface of the organic layer.

According to the embodiments, a display device capable of increasing an area contributing to display can be provided.

Embodiments will be described hereinafter with reference to the accompanying drawings.

The disclosure is merely an example, and proper changes within the spirit of the invention, which are easily conceivable by a person of ordinary skill in the art, are included in the scope of the invention as a matter of course. In addition, in order to make the description clearer, the widths, thicknesses, shapes and the like, of the respective parts are schematically illustrated in the drawings, compared to the actual modes, in some cases. However, the schematic illustration is merely an example, and adds no restriction to the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis and a Z-axis orthogonal to each other are described to facilitate understanding as needed. A direction along the X-axis is referred to as an X-direction or a first direction, a direction along the Y-axis is referred to as a Y-direction or a second direction, and a direction along the Z-axis is referred to as a Z-direction or a third direction. A plane defined by the X-axis and the Y-axis is referred to as an X-Y plane. Viewing the X-Y plane is referred to as plan view.

The display device DSP according to the embodiment is an organic electroluminescent display device comprising organic light emitting diodes (OLED) as display elements, and is mounted on televisions, personal computers, mobile terminals, mobile phones, and the like. The display element described below can be applied as a light emitting element of an illumination device, and the display device DSP can be applied to other electronic devices such as an illumination device.

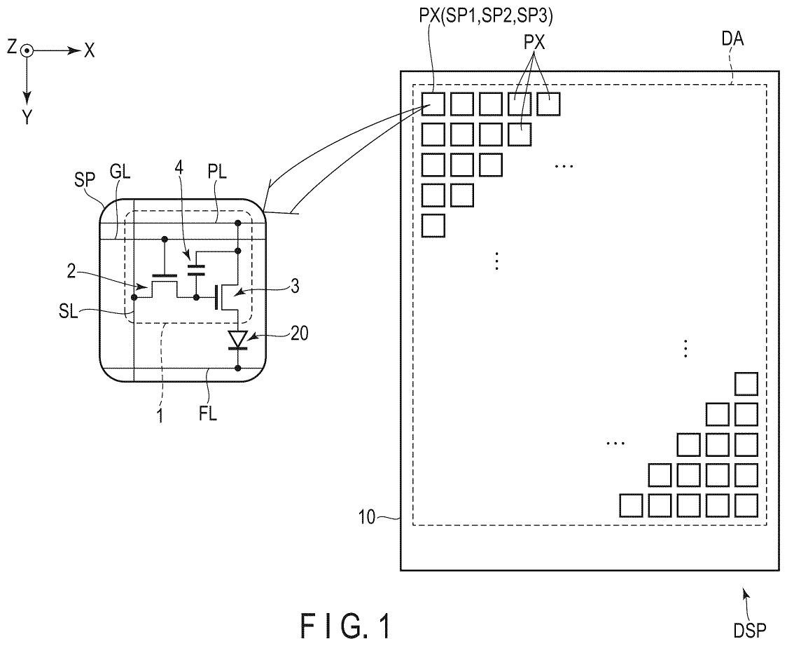

FIG. 1 is a view showing a configuration example of the display device DSP according to the embodiments. The display device DSP comprises a display portion DA where images are displayed, on an insulating substrate 10. The substrate 10 may be glass or a flexible resin film.

The display portion DA comprises a plurality of pixels PX arrayed in a matrix in the first direction X and the second direction Y. The pixel PX comprises a plurality of sub-pixels SP1, SP2, and SP3. As an example, the pixel PX comprises a red sub-pixel SP1, a green sub-pixel SP2, and a blue sub-pixel SP3. In addition to the sub-pixels of the above three colors, the pixel PX may comprise four or more sub-pixels including a sub-pixel of the other color such as white.

A configuration example of one sub-pixel SP included in the pixel PX will be described simply.

In other words, the sub-pixel SP comprises a pixel circuit 1 and a display element 20 driven by the pixel circuit 1. The pixel circuit 1 comprises a pixel switch 2, a drive transistor 3, and a capacitor 4. The pixel switch 2 and the drive transistor 3 are, for example, switch elements constituted by thin-film transistors.

In the pixel switch 2, a gate electrode is connected to a scanning line GL, a source electrode is connected to a signal line SL, and a drain electrode is connected to one of electrodes constituting the capacitor 4 and a gate electrode of the drive transistor 3. In the drive transistor 3, a source electrode is connected to the other electrode constituting the capacitor 4 and a power line PL, and a drain electrode is connected to an anode of the display element 20. A cathode of the display element 20 is connected to a power supply line FL. The configuration of the pixel circuit 1 is not limited to the example shown in the figure.

The display element 20 is an organic light emitting diode (OLED) which is a light emitting element. For example, the sub-pixel SP1 comprises a display element that emits light corresponding to a red wavelength, the sub-pixel SP2 comprises a display element that emits light corresponding to a green wavelength, and the sub-pixel SP3 comprises a display element that emits light corresponding to a blue wavelength. The pixel PX can realize multicolor display by comprising a plurality of sub-pixels SP1, SP2, and SP3 of different display colors.

However, the pixel PX may also be configured such that the display element 20 of each of the sub-pixels SP1, SP2, and SP3 emits light of the same color. Monochromatic display can be thereby realized.

In addition, when the display element 20 of each of the sub-pixels SP1, SP2, and SP3 is configured to emit white light, a color filter opposed to the display element 20 may be arranged. For example, the sub-pixel SP1 may comprise a red color filter opposed to the display element 20, the sub-pixel SP2 may comprise a green color filter opposed to the display element 20, and the sub-pixel SP3 may comprise a blue color filter opposed to the display element 20. Multicolor display can be thereby realized.

Alternatively, when the display element 20 of each of the sub-pixels SP1, SP2, and SP3 is configured to emit ultraviolet light, multicolor display can be realized by arranging a light conversion layer opposed to the display element 20.

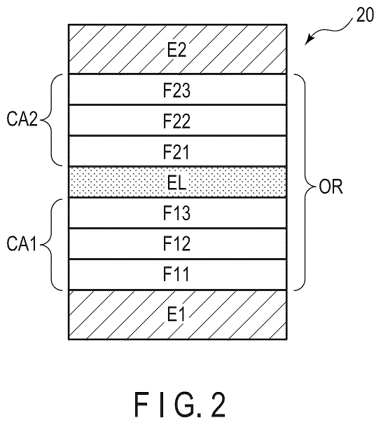

FIG. 2 is a view showing an example of a configuration of the display element 20.

The display element 20 comprises a lower electrode (first electrode) E1, an organic layer OR, and an upper electrode (second electrode) E2. The organic layer OR includes a carrier adjustment layer (first carrier adjustment layer) CA1, a light emitting layer EL, and a carrier adjustment layer (second carrier adjustment layer) CA2. The carrier adjustment layer CA1 is located between the lower electrode E1 and the light emitting layer EL, and the carrier adjustment layer CA2 is located between the light emitting layer EL and the upper electrode E2. The carrier adjustment layers CA1 and CA2 include a plurality of functional layers.

An example in which the lower electrode E1 corresponds to an anode and the upper electrode E2 corresponds to a cathode will be described.

The carrier adjustment layer CA1 includes a hole injection layer F11, a hole transport layer F12, an electron blocking layer F13, and the like, as functional layers. The hole injection layer F11 is arranged on the lower electrode E1, the hole transport layer F12 is arranged on the hole injection layer F11, the electron blocking layer F13 is arranged on the hole transport layer F12, and the light emitting layer EL is arranged on the electron blocking layer F13.

The carrier adjustment layer CA2 includes a hole blocking layer F21, an electron transport layer F22, an electron injection layer F23, and the like, as functional layers. The hole blocking layer F21 is arranged on the light emitting layer EL, the electron transport layer F22 is arranged on the hole blocking layer F21, the electron injection layer F23 is arranged on the electron transport layer F22, and the upper electrode E2 is arranged on the electron injection layer F23.

In addition to the functional layers described above, the carrier adjustment layers CA1 and CA2 may also include the other functional layers such as a carrier generation layer as needed or at least one of the above functional layers may be omitted in the carrier adjustment layers CA1 and CA2.

<<Basic Structure>>

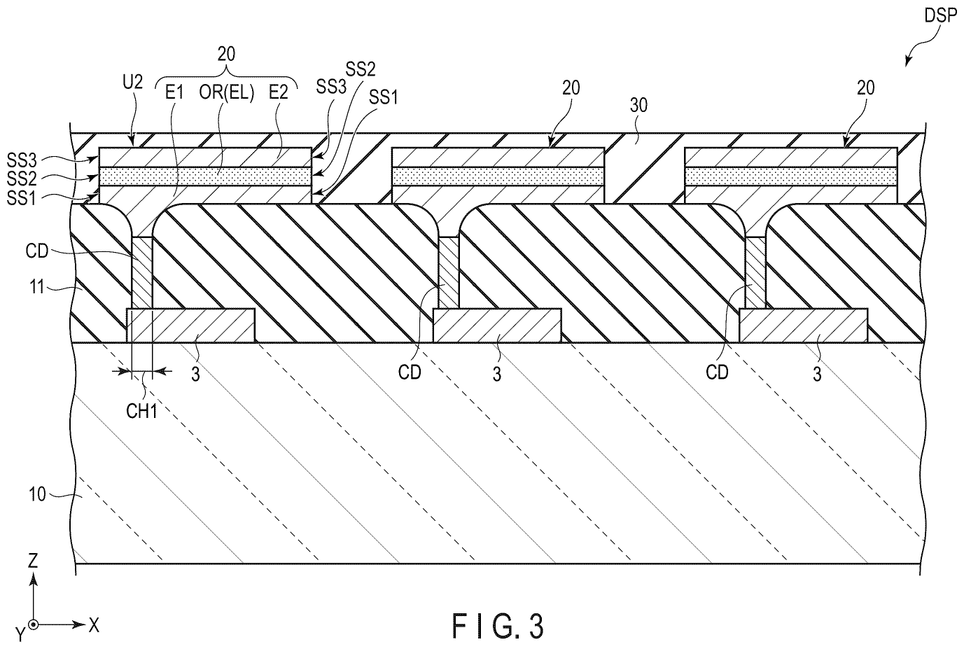

FIG. 3 is a cross-sectional view showing a basic structure of the display device DSP.

The pixel circuit 1 shown in FIG. 1 is arranged above the substrate 10. In FIG. 3, only a drive transistor (switching element) 3 included in the pixel circuit 1 is simplified and shown.

The insulating layer (first insulating layer) 11 is arranged above the substrate 10 and corresponds to an underlying layer of the display element 20. The insulating layer 11 is, for example, an organic insulating layer. The insulating layer 11 includes a contact hole (first contact hole) CH1 that penetrates to the drive transistor 3. A conductive material CD is filled in the contact hole CH1 and is in contact with the drive transistor 3. The conductive material CD is formed of, for example, a material containing metals such as titanium (Ti), molybdenum (Mo), tungsten (W), magnesium (Mg), silver (Ag), and tantalum (Ta).

The display element 20 comprises a lower electrode E1, an organic layer OR, and an upper electrode E2.

The lower electrodes E1 of the respective display elements 20 are arranged at intervals in the first direction X, and each of them is arranged on the insulating layer 11. Each of the lower electrodes E1 is in contact with the conductive material CD and is electrically connected to the drive transistor 3. The lower electrode E1 is an electrode arranged for each sub-pixel or each display element and is referred to as a pixel electrode, an anode or the like in some cases.

The lower electrode E1 is, for example, a transparent electrode formed of a transparent conductive material such as indium tin oxide (ITO) or indium zinc oxide (IZO). The lower electrode E1 may be a metal electrode formed of a metal material such as silver or aluminum. Alternatively, the lower electrode E1 may be a stacked layer body of transparent electrodes and metal electrodes. For example, the lower electrode E1 may be constituted as a stacked layer body formed by stacking a transparent electrode, a metal electrode, and a transparent electrode, in this order, or may be constituted as a stacked layer body of three or more layers. In this case, the transparent electrode containing a conductive material different from the conductive material CD, of the lower electrode E1, is in contact with the conductive material CD. However, the electrode of the same material as the conductive material CD, of the lower electrode E1, may be in contact with the conductive material CD.

The organic layer OR includes a light emitting layer EL as shown in FIG. 2. The organic layers OR of the display elements 20 are stacked on the lower electrodes E11, respectively, and separated from each other. The organic layers OR of the respective display elements 20 arranged in the first direction X may include the light emitting layers EL formed of materials different from each other (the organic layers OR in the respective display elements 20 may emit light of different colors) or may include the light emitting layers EL formed of the same material (the organic layers OR in the respective display elements 20 may emit light of the same color).

The upper electrodes E2 of the display elements 20 are stacked on the organic layers OR, respectively, and are separated from each other. The upper electrodes E2 stacked on the organic layers OR arranged in the second direction Y may be formed integrally. The upper electrode E2 is electrically connected to the power supply line inside the display portion DA or outside the display portion DA, which will be described later. The upper electrode E2 is referred to as a common electrode, a counter-electrode, a cathode or the like in some cases.

The upper electrode E2 is, for example, a transflective metal electrode formed of a metal material such as magnesium and silver. The upper electrode E2 may be a transparent electrode formed of a transparent conductive material such as ITO or IZO. Alternatively, the upper electrode E2 may be a stacked layer body of transparent electrodes and metal electrodes.

A substantially entire body of the organic layer OR is located between the lower electrode E1 and the upper electrode E2, and can form a light emission area of the display element 20. In one example, a thickness of the organic layer OR along the third direction Z is set such that a peak wavelength of the emission spectrum in the light emitting layer EL matches an effective optical path length between the lower electrode E1 and the upper electrode E2. A microcavity structure for obtaining a resonance effect is thereby realized.

In the example shown in FIG. 3, an end surface SS1 of the lower electrode E1 is exposed from the organic layer OR and the upper electrode E2. An end surface SS2 of the organic layer OR is located on the lower electrode E1 and is exposed from the upper electrode E2. An end surface SS3 of the upper electrode E2 is located on the organic layer OR.

A sealing layer 30 covers each display element 20. In other words, the sealing layer 30 covers each of the end surface SS1 of the lower electrode E1, the end surface SS2 of the organic layer OR, and the end surface SS3 and the upper surface U2 of the upper electrode E2. In addition, the sealing layer 30 is in contact with the insulating layer 11 at a position between the adjacent display elements 20. The sealing layer 30 is, for example, a stacked layer body of inorganic insulating films and organic insulating films. Such a sealing layer 30 comprises a function of protecting each display element 20 from moisture and the like.

According to such a display device DSP, a substantially entire body of the organic layer OR can be formed as the light emission area of the display element 20, and the area contributing to the display or light emission (area of the light emission area) can be increased, as compared with a configuration in which a rib covering the peripheral part of the lower electrode E1 is provided. In addition, undesired light emission in an area different from the predetermined light emission area is suppressed, and degradation of the color purity can be suppressed.

<<First Structural Example>>

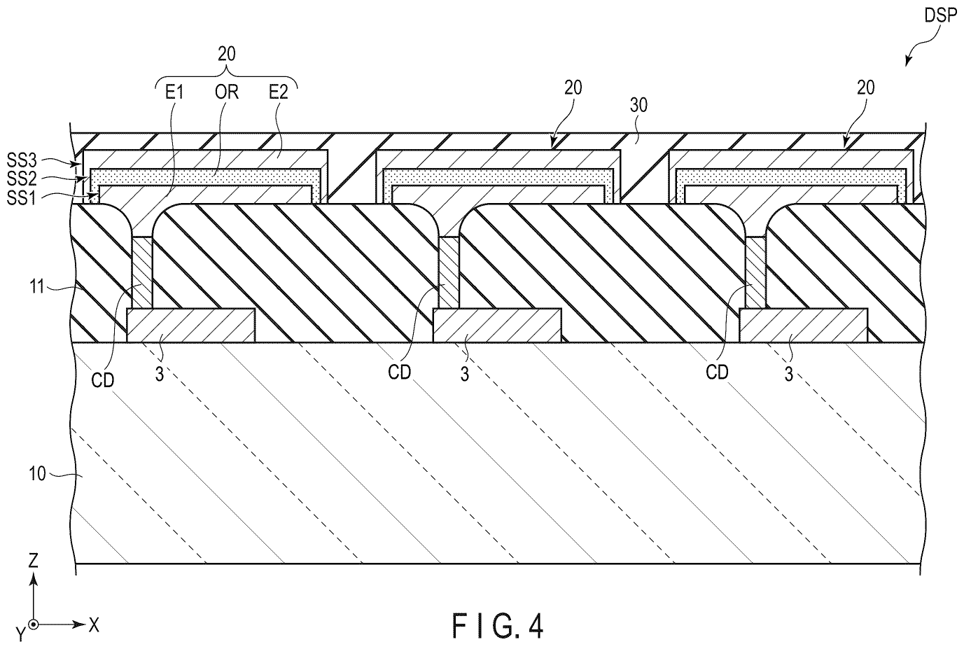

FIG. 4 is a cross-sectional view showing a first structural example of the display device DSP.

The first structural example shown in FIG. 4 is different from the basic structure shown in FIG. 3 in that the organic layer OR covers the end surface SS1 of the lower electrode E1. The organic layer OR is in contact with the insulating layer 11 outside the lower electrode E1. The upper electrode E2 is stacked on the organic layer OR to cover the end surface SS2 of the organic layer OR. The upper electrode E2 is in contact with the insulating layer 11 outside the organic layer OR. The upper electrodes E2 of the respective display elements 20 arranged in the first direction X are separated from each other.

The sealing layer 30 covers the upper electrodes E2. In other words, the sealing layer 30 is in contact with the end surfaces SS3 of the upper electrodes E2. In addition, the sealing layer 30 is in contact with the insulating layer 11 between the adjacent display elements 20.

According to such a first structural example, the same advantages as those of the above-described basic structure can be obtained. In addition, since the organic layer OR covers the end surface SS1 of the lower electrode E1, a short circuit between the lower electrode E1 and the upper electrode E2 can be suppressed.

<<Second Structural Example>>

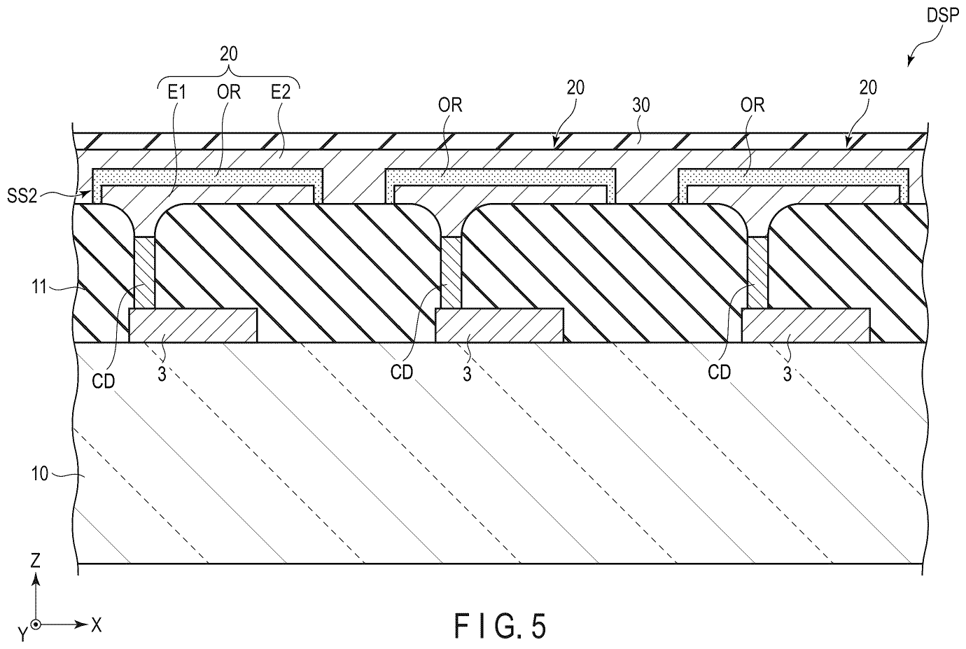

FIG. 5 is a cross-sectional view showing a second structural example of the display device DSP.

The second structural example shown in FIG. 5 is different from the first structural example shown in FIG. 4 in that the upper electrode E2 of each of the display elements 20 arranged in the first direction X is formed integrally. The upper electrode E2 covers the end surface SS2 of each of the organic layers OR arranged in the first direction X. The upper electrode E2 is in contact with the insulating layer 11 between the organic layers OR arranged in the first direction X.

The sealing layer 30 is stacked on the upper electrode E2 and is separated from the insulating layer 11.

In such a second structural example, the same advantages as those of the first configuration example can also be obtained.

Next, an example of the display element 20 based on the concepts of the first structural example and the second structural example will be described. Illustration of layers under the insulating layer 11 is omitted.

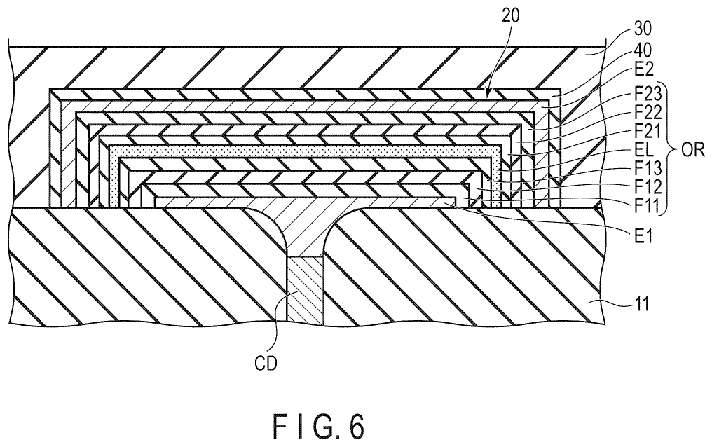

FIG. 6 is a cross-sectional view showing a first example of the display element 20.

The hole injection layer F11 covers an entire body of the lower electrode E1, the hole transport layer F12 covers an entire body of the hole injection layer F11, the electron blocking layer F13 covers an entire body of the hole transport layer F12, and the light emitting layer EL covers an entire body of the electron blocking layer F13. The expression “covering an entire body” means covering an upper surface and an end surface (side surface) of a member.

The hole blocking layer F21 covers an entire body of the light emitting layer EL, the electron transport layer F22 covers an entire body of the hole blocking layer F21, the electron injection layer F23 covers an entire body of the electron transport layer F22, and the upper electrode E2 covers an entire body of the electron injection layer F23.

A light extraction layer (also referred to as an optical adjustment layer) 40 for improving a light extraction efficiency from the display element 20 covers an entire body of the upper electrode E2. The sealing layer 30 covers an entire body of the light extraction layer 40. Each of the layers constituting the organic layer OR, the upper electrode E2, the light extraction layer 40, and the sealing layer 30 is in contact with the insulating layer 11.

According to such a first example, the upper electrode E2 is in contact with the electron injection layer F23 located in the uppermost layer of the organic layer OR, but is not in contact with the other functional layers constituting the organic layer OR or the light emitting layer EL. For this reason, undesired current leakage at the peripheral part of the organic layer OR and the like are suppressed, and the degradation in the performance of the display element 20 can be suppressed.

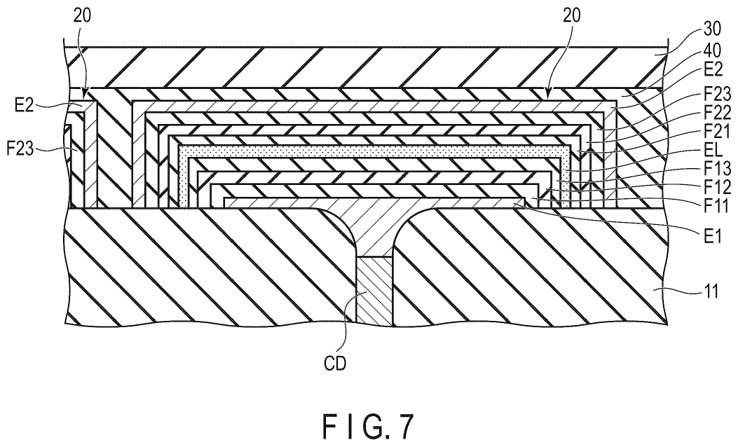

FIG. 7 is a cross-sectional view showing a second example of the display element 20.

The second example shown in FIG. 7 is different from the first example shown in FIG. 6 in that the light extraction layer 40 is formed integrally over the adjacent display elements 20. In other words, the light extraction layer 40 covers the adjacent upper electrodes E2 and is in contact with the insulating layer 11 between the adjacent upper electrodes E2. The sealing layer 30 is stacked on the light extraction layer 40 and is separated from the insulating layer 11.

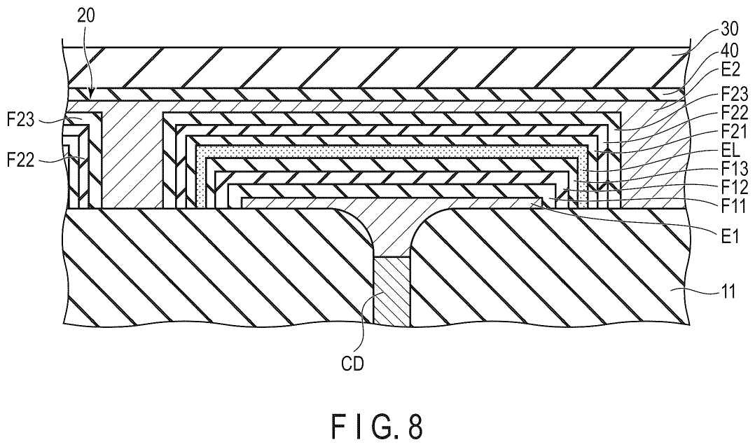

FIG. 8 is a cross-sectional view showing a third example of the display element 20.

The third example shown in FIG. 8 is different from the first example shown in FIG. 6 in that the upper electrode E2 is formed integrally over the adjacent display elements 20. In other words, the upper electrode E2 covers the adjacent electron injection layers F23 and is in contact with the insulating layer 11 between the adjacent electron injection layers F23. The sealing layer 30 and the light extraction layer 40 are separated from the insulating layer 11.

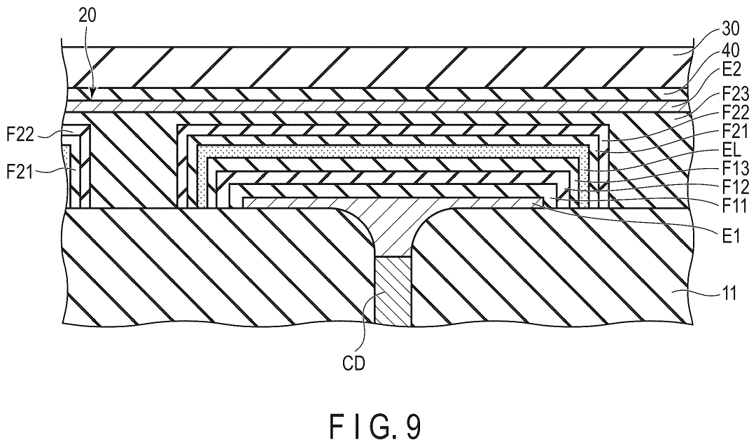

FIG. 9 is a cross-sectional view showing a fourth example of the display element 20.

The fourth example shown in FIG. 9 is different from the first example shown in FIG. 6 in that the electron injection layer F23 is formed integrally over the adjacent display elements 20. In other words, the electron injection layer F23 covers the adjacent electron transport layers F22 and is in contact with the insulating layer 11 between the adjacent electron transport layers F22. The sealing layer 30, the light extraction layer 40, and the upper electrode E2 are separated from the insulating layer 11.

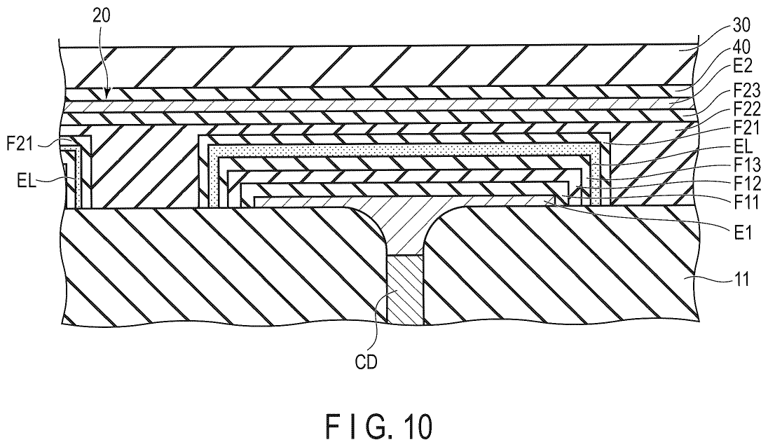

FIG. 10 is a cross-sectional view showing a fifth example of the display element 20.

The fifth example shown in FIG. 10 is different from the first example shown in FIG. 6 in that the electron transport layer F22 is formed integrally over the adjacent display elements 20. In other words, the electron transport layer F22 covers the adjacent hole blocking layers F21 and is in contact with the insulating layer 11 between the adjacent hole blocking layers F21. The sealing layer 30, the light extraction layer 40, the upper electrode E2, and the electron injection layer F23 are separated from the insulating layer 11.

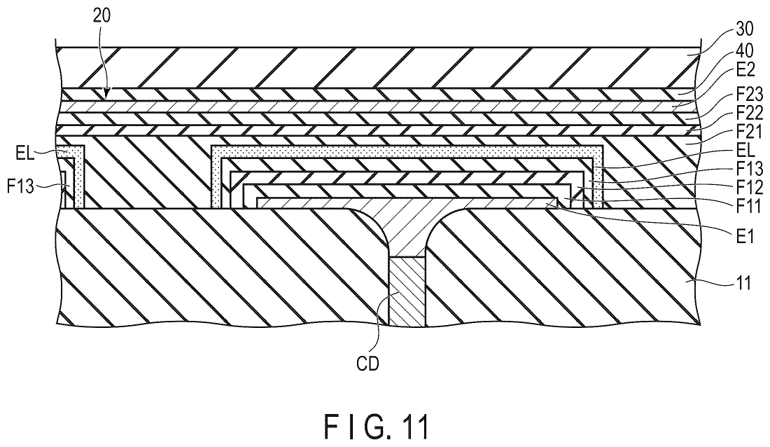

FIG. 11 is a cross-sectional view showing a sixth example of the display element 20.

The sixth example shown in FIG. 11 is different from the first example shown in FIG. 6 in that the hole blocking layer F21 is formed integrally over the adjacent display elements 20. In other words, the hole blocking layer F21 covers the adjacent light emitting layers EL and is in contact with the insulating layer 11 between the adjacent light emitting layers EL. The sealing layer 30, the light extraction layer 40, the upper electrode E2, the electron injection layer F23, and the electron transport layer F22 are separated from the insulating layer 11.

In the second to sixth examples, too, the same advantages as those of the first example can be obtained.

<<Third Structural Example>>

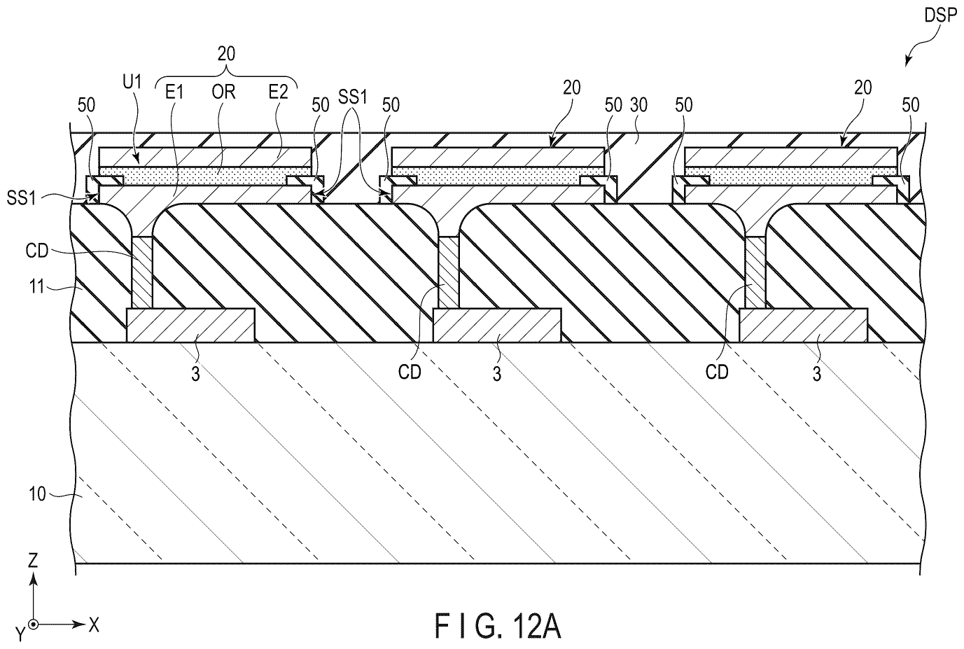

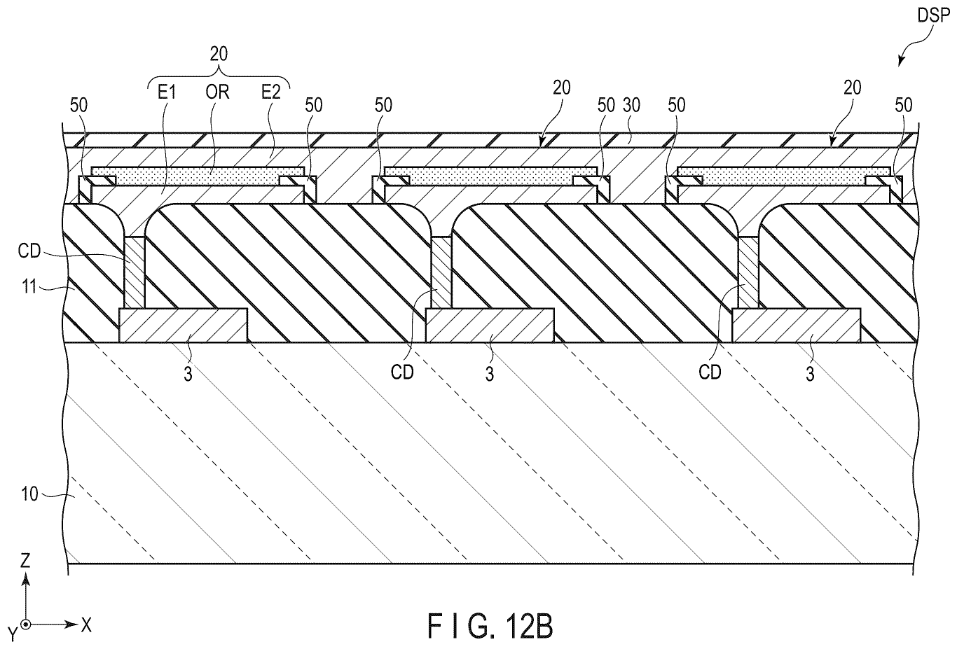

FIG. 12A is a cross-sectional view showing a third structural example of the display device DSP.

The third structural example shown in FIG. 12A is different from the basic structure shown in FIG. 3 in that a coating layer 50 which covers the end surface SS1 of the lower electrode E1 is provided. The coating layer 50 is an insulator and may be formed of an inorganic material or may be formed of an organic material. In addition, the coating layer 50 may be formed using at least one of the electron blocking layer F13 which blocks movement of electrons from the cathode side to the anode side, and the hole blocking layer F21 which blocks movement of a hole from the anode side to the cathode side, which will be described later.

The coating layer 50 is provided independently for each of the lower electrode E1 arranged in the first direction X. In other words, the coating layer 50 provided to correspond to one of the lower electrode E1, of two lower electrodes E1 arranged in the first direction X, is separated from the coating layer 50 provided to correspond to the other lower electrode E1. The insulating layer 11 is exposed between the adjacent coating layers 50.

From the viewpoint of increasing the area of the light emission area as much as possible, an area covered with the coating layer 50, of the upper surface U1 of the lower electrode E1, is desirably as small as possible.

The sealing layer 30 covers the upper electrode E2 and the organic layer OR of each of the display elements 20 arranged in the first direction X, and also covers the coating layer 50. In addition, the sealing layer 30 is in contact with the insulating layer 11 between the coating layers 50 arranged in the first direction X.

According to such a third structural example, the same advantages as those of the above-described basic structure can be obtained. In addition, since the coating layer 50 covers the end surface SS1 of the lower electrode E1, a short circuit between the lower electrode E1 and the upper electrode E2 can be suppressed.

<<Fourth Structural Example>>

FIG. 12B is a cross-sectional view showing a fourth structural example of the display device DSP.

The fourth structural example shown in FIG. 12B is different from the third structural example shown in FIG. 12A in that the upper electrode E2 of each of the display elements 20 arranged in the first direction X is formed integrally. The upper electrode E2 covers the organic layer OR of each of the display elements 20 arranged in the first direction X, and also covers the coating layer 50. In addition, the upper electrode E2 is in contact with the insulating layer 11 between the coating layers 50 arranged in the first direction X.

The sealing layer 30 is stacked on the upper electrode E2 and is separated from the insulating layer 11.

In such a fourth structural example, the same advantages as those of the third structural example can also be obtained.

<<Fifth Structural Example>>

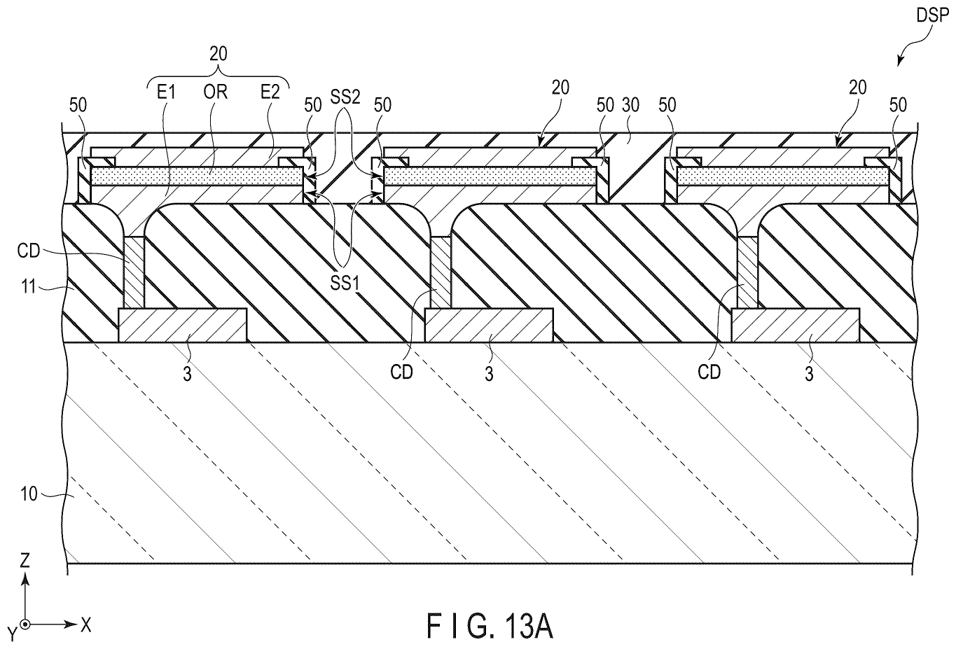

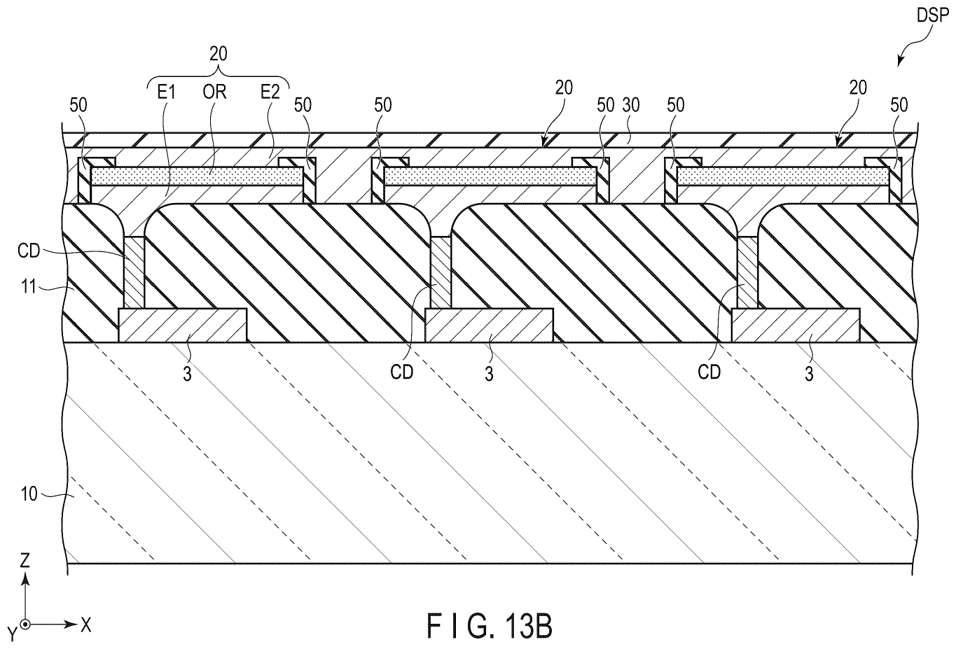

FIG. 13A is a cross-sectional view showing a fifth structural example of the display device DSP.

The fifth structural example shown in FIG. 13A is different from the third structural example shown in FIG. 12A in that the coating layer 50 covers the end surface SS1 of the lower electrode E1 and the end surface SS2 of the organic layer OR. The insulating layer 11 is exposed between the adjacent coating layers 50.

The sealing layer 30 covers the upper electrode E2 of each of the display elements 20 arranged in the first direction X, and also covers the coating layer 50. In addition, the sealing layer 30 is in contact with the insulating layer 11 between the coating layers 50 arranged in the first direction X.

In such a fifth structural example, the same advantages as those of the third structural example can also be obtained. In addition, since the coating layer 50 covers an end surface of each layer constituting the organic layer OR, undesired current leakage at the peripheral part of the organic layer OR and the like are suppressed, and the degradation in the performance of the display element 20 can be suppressed.

<<Sixth Structural Example>>

FIG. 13B is a cross-sectional view showing a sixth structural example of the display device DSP.

The sixth structural example shown in FIG. 13B is different from the fifth structural example shown in FIG. 13A in that the upper electrode E2 of each of the display elements 20 arranged in the first direction X is formed integrally. The upper electrode E2 covers the organic layer OR of each of the display elements 20 arranged in the first direction X, and also covers the coating layer 50. In addition, the upper electrode E2 is in contact with the insulating layer 11 between the coating layers 50 arranged in the first direction X.

The sealing layer 30 is stacked on the upper electrode E2 and is separated from the insulating layer 11.

In such a sixth structural example, the same advantages as those of the fifth structural example can also be obtained.

<<Seventh Structural Example>>

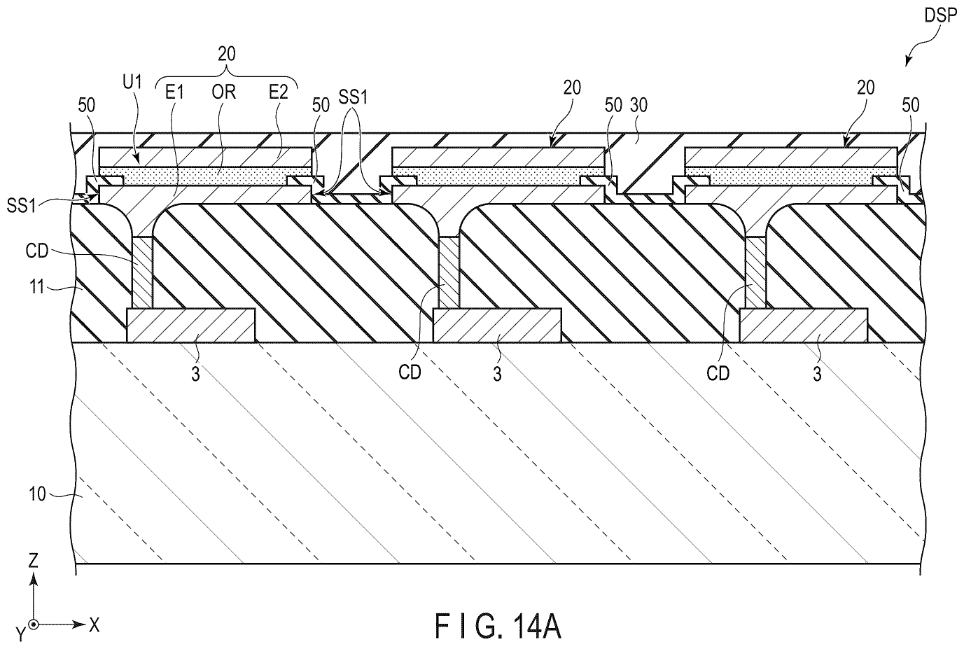

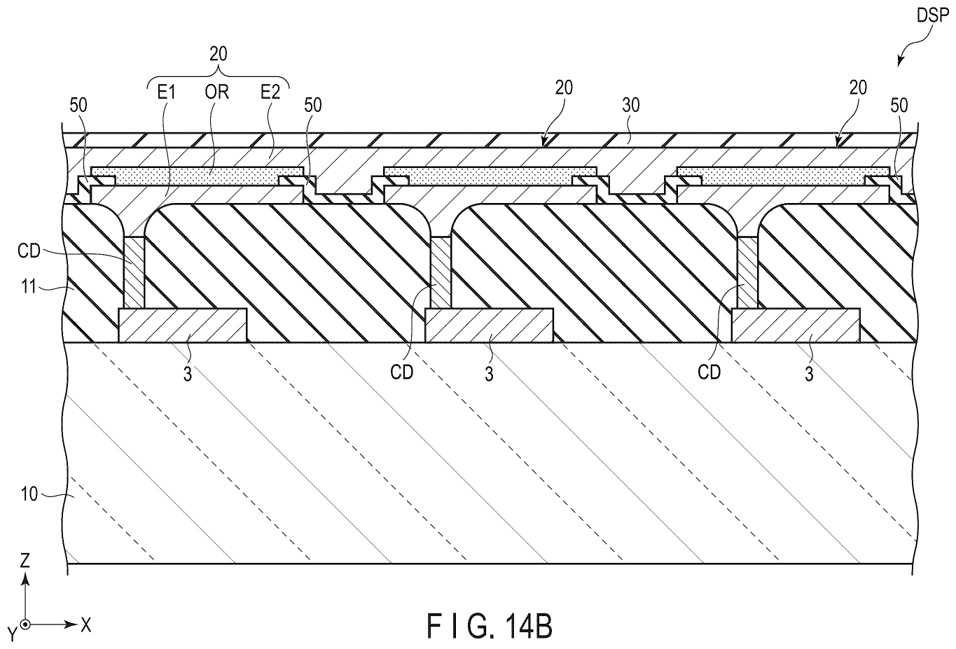

FIG. 14A is a cross-sectional view showing a seventh structural example of the display device DSP.

The seventh structural example shown in FIG. 14A is different from the third structural example shown in FIG. 12A in that the coating layer 50 which covers each of the end surfaces SS1 of the adjacent lower electrodes E1 is formed integrally. The insulating layer 11 is covered with the coating layer 50 between the adjacent lower electrodes E1.

The sealing layer 30 covers the upper electrode E2 of each of the display elements 20 arranged in the first direction X, and also covers the coating layer 50.

In such a seventh structural example, the same advantages as those of the third structural example can also be obtained.

<<Eighth Structural Example>>

FIG. 14B is a cross-sectional view showing an eighth structural example of the display device DSP.

The eighth structural example shown in FIG. 14B is different from the seventh structural example shown in FIG. 14A in that the upper electrode E2 of each of the display elements 20 arranged in the first direction X is formed integrally. The upper electrode E2 covers the organic layer OR of each of the display elements 20 arranged in the first direction X, and also covers the coating layer 50. The upper electrode E2 and the sealing layer 30 are separated from the insulating layer 11 between the display elements 20 arranged in the first direction X.

In such an eighth structural example, the same advantages as those of the third structural example can also be obtained.

<<Ninth Structural Example>>

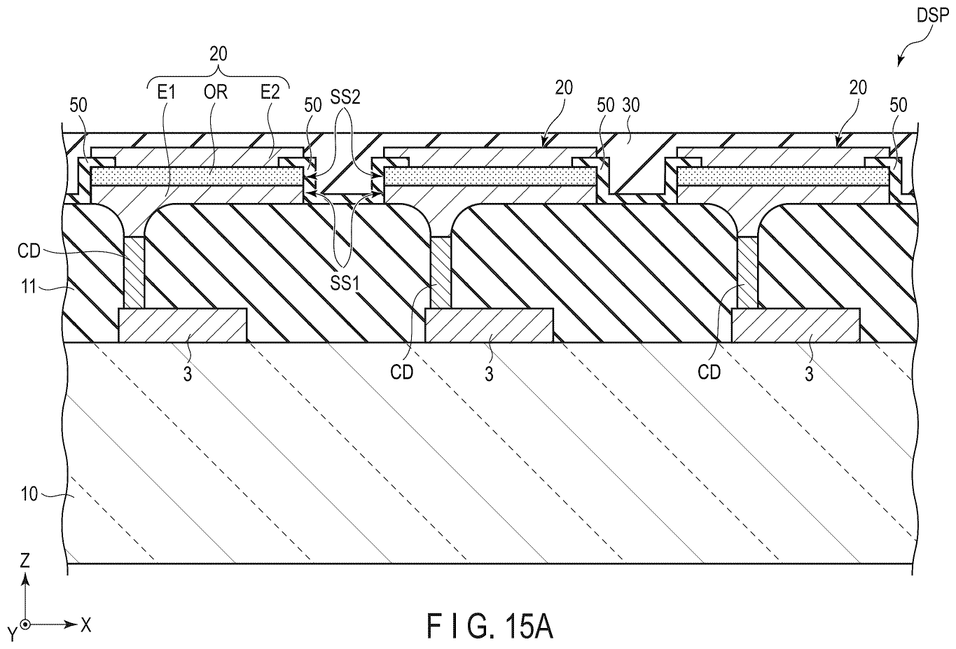

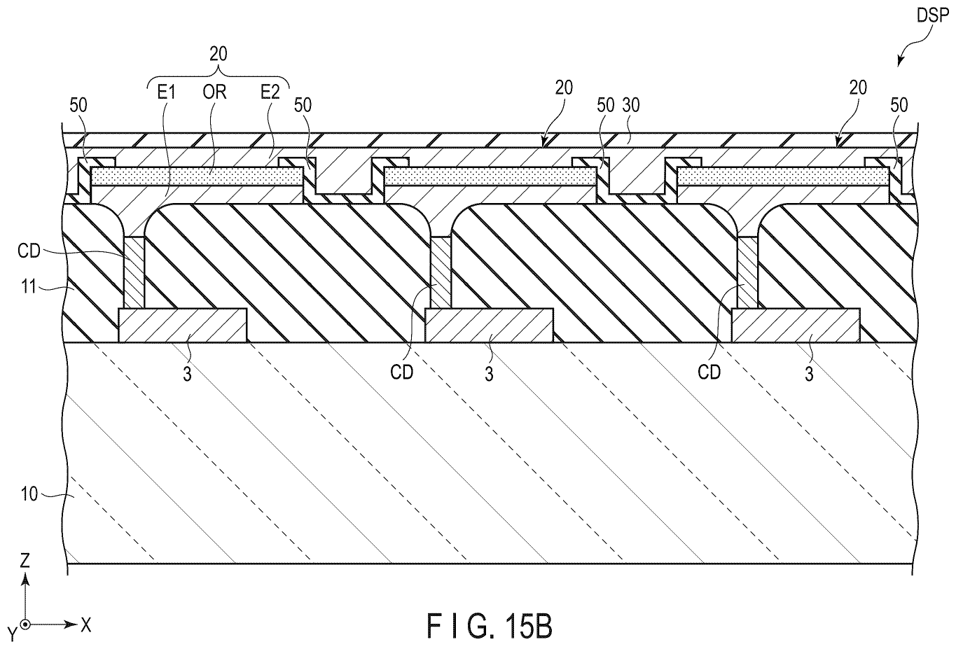

FIG. 15A is a cross-sectional view showing a ninth structural example of the display device DSP.

The ninth structural example shown in FIG. 15A is different from the seventh structural example shown in FIG. 14A in that the coating layer 50 covers the end surface SS1 of the lower electrode E1 and the end surface SS2 of the organic layer OR. The insulating layer 11 is covered with the coating layer 50 between the adjacent lower electrodes E1.

The sealing layer 30 covers the upper electrode E2 of each of the display elements 20 arranged in the first direction X, and also covers the coating layer 50.

In such a ninth structural example, the same advantages as those of the third structural example can also be obtained.

<<Tenth Structural Example>>

FIG. 15B is a cross-sectional view showing a tenth structural example of the display device DSP.

The tenth structural example shown in FIG. 15B is different from the ninth structural example shown in FIG. 15A in that the upper electrode E2 of each of the display elements 20 arranged in the first direction X is formed integrally. The upper electrode E2 covers the organic layer OR of each of the display elements 20 arranged in the first direction X, and also covers the coating layer 50. The upper electrode E2 and the sealing layer 30 are separated from the insulating layer 11 between the display elements 20 arranged in the first direction X.

In such a tenth structural example, the same advantages as those of the third structural example can also be obtained.

Next, an example of the display element 20 based on the concepts of the third structural example, the fourth structural example, the fifth structural example, the sixth structural example, the seventh structural example, the eighth structural example, the ninth structural example, and the tenth structural example will be described. Illustration of layers under the insulating layer 11 is omitted.

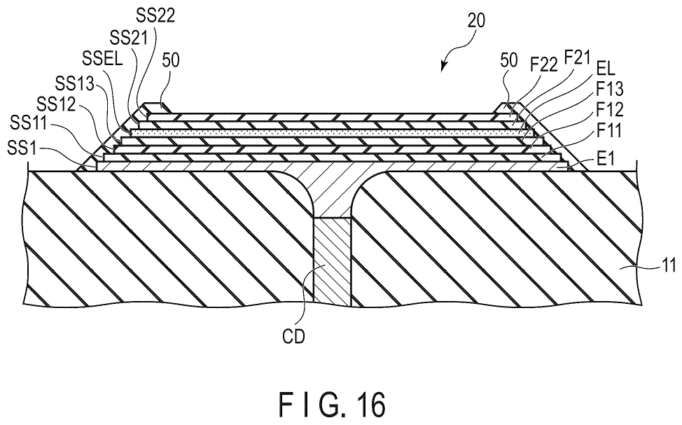

FIG. 16 is a cross-sectional view showing a seventh example of the display element 20.

An end surface SS11 of the hole injection layer F11 is located on the lower electrode E1. An end surface SS12 of the hole transport layer F12 is located on the hole injection layer F11. The coating layer 50 covers the end surface SS1 of the lower electrode E1, the end surface SS11 of the hole injection layer F11, and the end surface SS12 of the hole transport layer F12.

An end surface SS13 of the electron blocking layer F13 is located on the coating layer 50. An end surface SSEL of the light emitting layer EL is located on the electron blocking layer F13. Illustration of the layers above the light emitting layer EL is omitted, but each of the layers constituting the organic layer OR is formed such that area of upper layers is smaller than area of lower layers. In other words, each of the layers constituting the display element 20 is formed such that upper layers have smaller area.

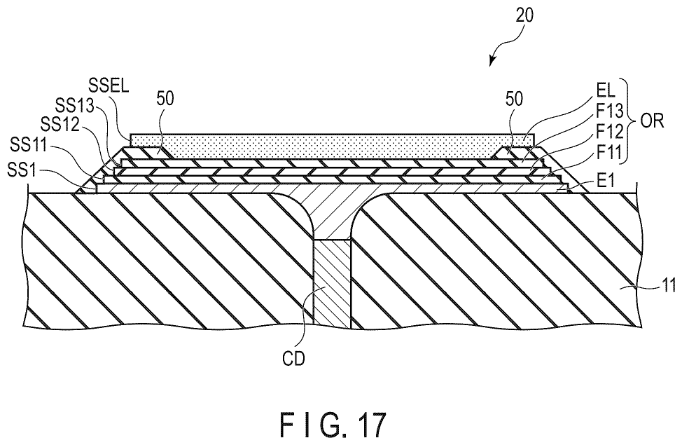

FIG. 17 is a cross-sectional view showing an eighth example of the display element 20.

The eighth example shown in FIG. 17 is different from the seventh example shown in FIG. 16 in that the coating layer 50 covers an end surface SS13 of the electron blocking layer F13 in addition to the end surface SS1, the end surface SS11, and the end surface SS12. The end surface SSEL of the light emitting layer EL is located on the coating layer 50.

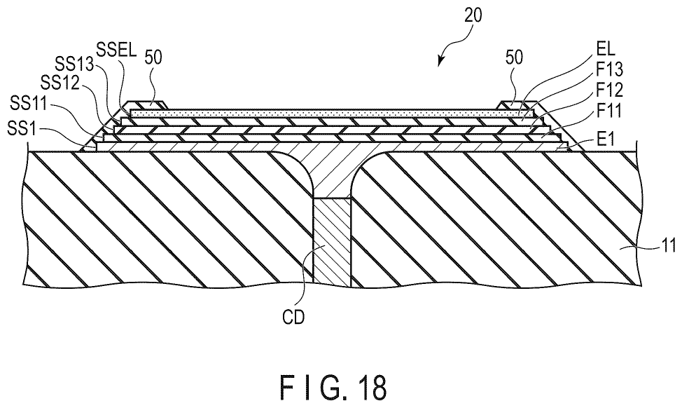

FIG. 18 is a cross-sectional view showing a ninth example of the display element 20.

The ninth example shown in FIG. 18 is different from the eighth example shown in FIG. 17 in that the coating layer 50 covers the end surface SSEL of the light emitting layer EL in addition to the end surface SS1, the end surface SS11, the end surface SS12, and the end surface SS13. The end surface SSEL is located on the electron blocking layer F13.

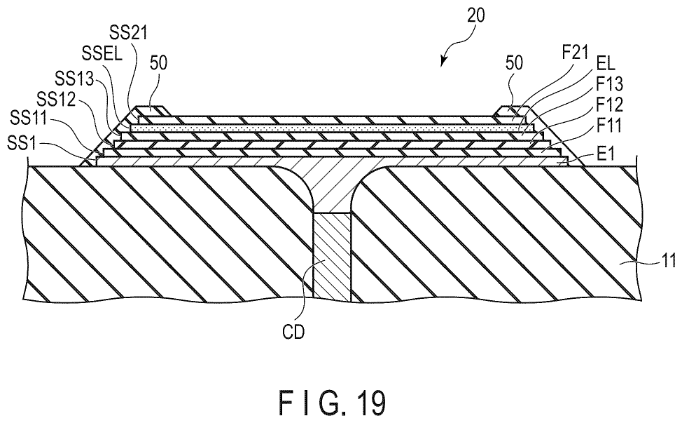

FIG. 19 is a cross-sectional view showing a tenth example of the display element 20.

The tenth example shown in FIG. 19 is different from the ninth example shown in FIG. 18 in that the coating layer 50 covers an end surface SS21 of the hole blocking layer F21 in addition to the end surface SS1, the end surface SS11, the end surface SS12, the end surface SS13, and the end surface SSEL. The end surface SS21 is located on the light emitting layer EL. Illustration of the layers above the hole blocking layer F21 is omitted.

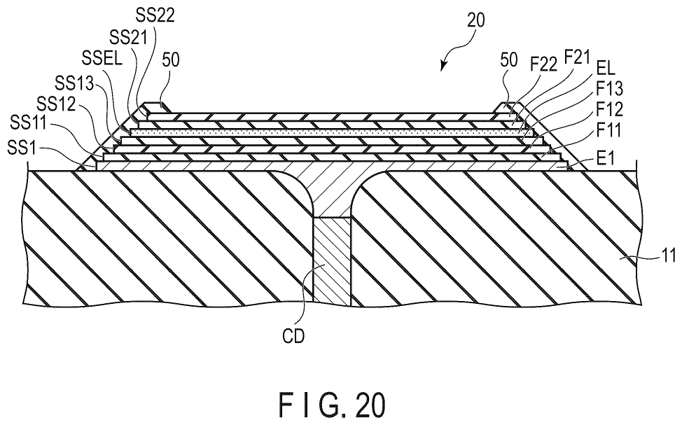

FIG. 20 is a cross-sectional view showing an eleventh example of the display element 20.

The eleventh example shown in FIG. 20 is different from the tenth example shown in FIG. 19 in that the coating layer 50 covers an end surface SS22 of the electron transport layer F22 in addition to the end surface SS1, the end surface SS11, the end surface SS12, the end surface SS13, the end surface SSEL, and the end surface SS21. The end surface SS22 is located on the hole blocking layer F21. Illustration of the layers above the electron transport layer F22 is omitted.

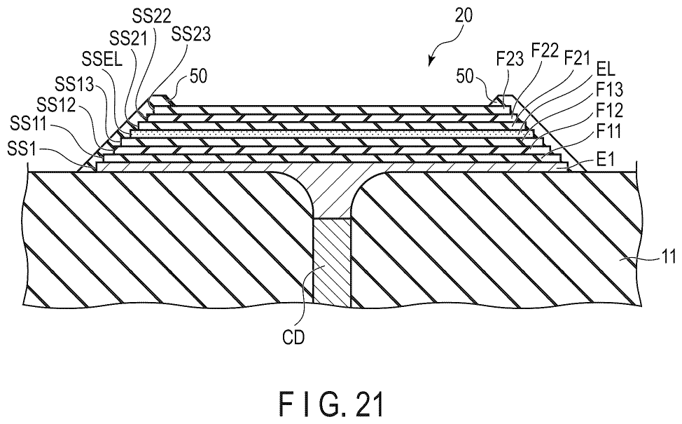

FIG. 21 is a cross-sectional view showing a twelfth example of the display element 20.

The twelfth example shown in FIG. 21 is different from the eleventh example shown in FIG. 20 in that the coating layer 50 covers an end surface SS23 of the electron injection layer F23 in addition to the end surface SS1, and the end surface SS11, the end surface SS12, the end surface SS13, the end surface SSEL, the end surface SS21, and the end surface SS22. The end surface SS23 is located on the electron transport layer F22. Illustration of the layers above the electron injection layer F23 is omitted.

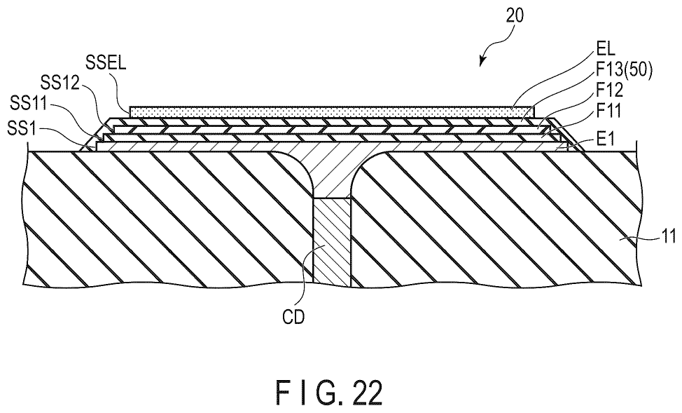

FIG. 22 is a cross-sectional view showing a thirteenth example of the display element 20.

The thirteenth example shown in FIG. 22 corresponds to an example in which that the electron blocking layer F13 constitutes the coating layer 50. In other words, the electron blocking layer F13 covers the lower electrode E1 including the end surface SS1, the hole injection layer F11 including the end surface SS11, and the hole transport layer F12 including the end surface SS12. The light emitting layer EL is located on the electron blocking layer F13. The electron blocking layer F13 is in contact with the insulating layer 11 outside the lower electrode E1. Illustration of the layers above the light emitting layer EL is omitted.

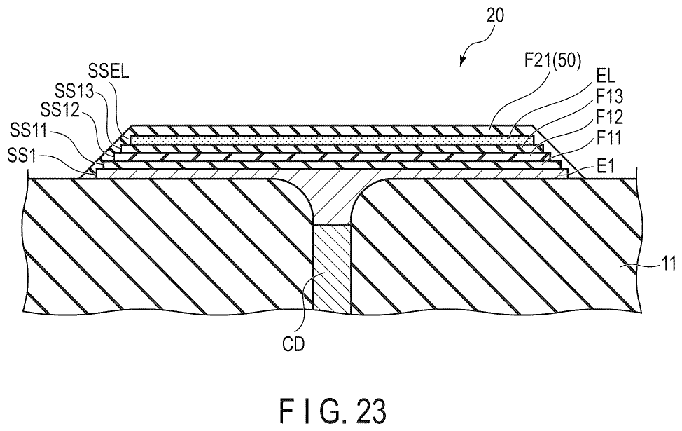

FIG. 23 is a cross-sectional view showing a fourteenth example of the display element 20.

The fourteenth example shown in FIG. 23 corresponds to an example in which that the hole blocking layer F21 constitutes the coating layer 50. In other words, the hole blocking layer F21 covers the lower electrode E1 including the end surface SS1, the hole injection layer F11 including the end surface SS11, the hole transport layer F12 including the end surface SS12, the electron blocking layer F13 including the end surface SS13, and the light emitting layer EL including the end surface SSEL. The hole blocking layer F21 is in contact with the insulating layer 11 outside the lower electrode E1. Illustration of the layers above the hole blocking layer F21 is omitted.

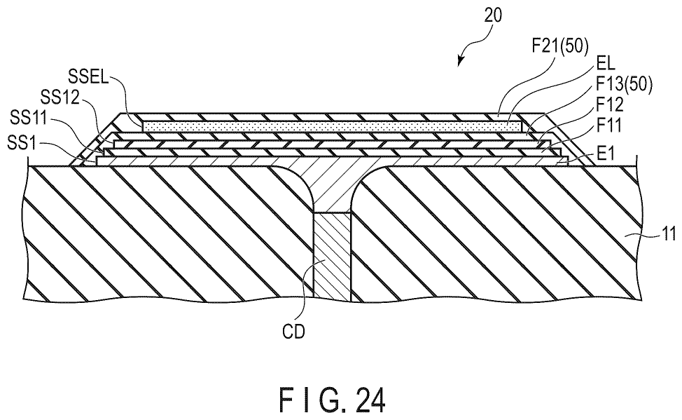

FIG. 24 is a cross-sectional view showing a fifteenth example of the display element 20.

The fifteenth example shown in FIG. 24 corresponds to an example in which that the electron blocking layer F13 and the hole blocking layer F21 constitute the coating layer 50. In other words, the electron blocking layer F13 covers the lower electrode E1 including the end surface SS1, the hole injection layer F11 including the end surface SS11, and the hole transport layer F12 including the end surface SS12. The light emitting layer EL is located on the electron blocking layer F13. The hole blocking layer F21 covers the electron blocking layer F13, and the light emitting layer EL including the end surface SSEL. The electron blocking layer F13 is in contact with the insulating layer 11 outside the lower electrode E1. The hole blocking layer F21 is in contact with the insulating layer 11 outside the electron blocking layer F13. Illustration of the layers above the hole blocking layer F21 is omitted.

In the above-described display element 20, the position and the shape of the contact hole CH1 (or the conductive material CD) for connecting the lower electrode E1 with the drive transistor 3 are not particularly limited.

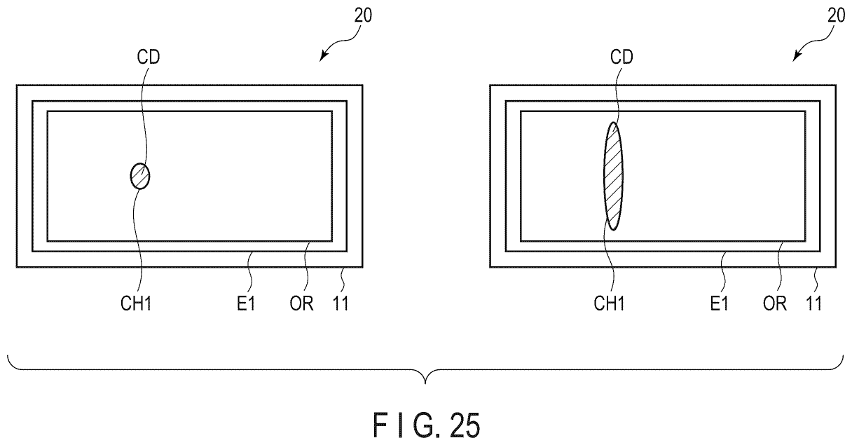

FIG. 25 is a schematic plan view showing the display element 20.

In an example shown on the left side of the drawing, the contact hole CH1 is formed in a substantially circular shape, and the conductive material CD is filled in the contact hole CH1. In an example shown on the right side of the drawing, the contact hole CH1 is formed in a substantially elliptic shape or oval shape, and the conductive material CD is filled in the contact hole CH1.

The position of the contact hole CH1 may be any position if the position is a position overlapping the lower electrode E1 in plan view. In addition, the shape of the contact hole CH1 may be a polygon such as a quadrangle. In addition, in plan view, a rate of area of the contact hole CH1 to area of the lower electrode E1 is minute in the example shown in FIG. 25, but the rate may be larger, for example, 50% or more and less than 100%.

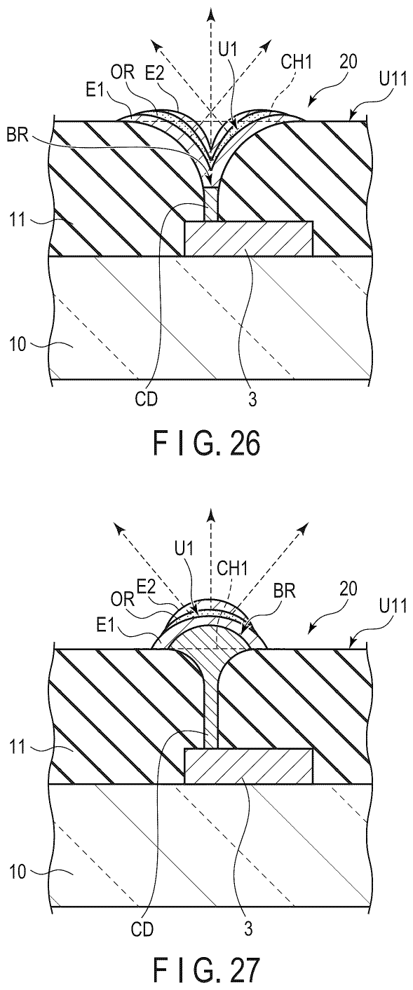

FIG. 26 is a cross-sectional view illustrating an example of a boundary surface BR between the conductive material CD and the lower electrode E1.

In the example shown in FIG. 26, the boundary surface BR is located below an upper surface U11 of the insulating layer 11. In other words, the conductive material CD is not filled to an upper end represented by a dotted line, in the contact hole CH1. The lower electrode E1 is arranged in the contact hole CH1 and is formed along an inclined surface of the insulating layer 11. For this reason, the lower electrode E1 has a recessed upper surface U1. The organic layer OR is arranged on the upper surface U1. The upper electrode E2 is arranged on the organic layer OR.

According to such a display element 20, since light is emitted in a direction indicated by an arrow of a dotted line, the viewing angle can be extended.

FIG. 27 is a cross-sectional view illustrating another example of the boundary surface BR between the conductive material CD and the lower electrode E1.

In the example shown in FIG. 27, the boundary surface BR is located above the upper surface U11 of the insulating layer 11. In other words, the conductive material CD is filled over the upper end represented by a dotted line, in the contact hole CH1. For this reason, the boundary surface BR is formed in an upwardly protruding shape. The lower electrode E1 has a protruding upper surface U1. The organic layer OR is arranged on the upper surface U1. The upper electrode E2 is arranged on the organic layer OR.

In such a display element 20, since light is emitted in a direction indicated by an arrow of a dotted line, the viewing angle can also be extended.

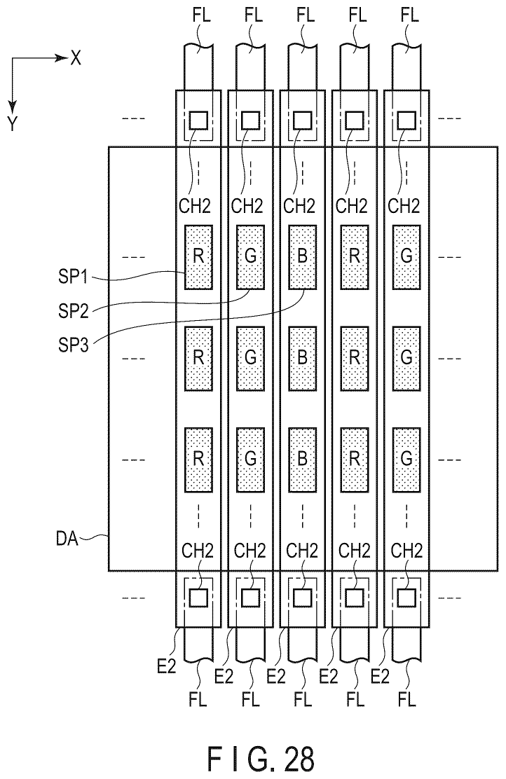

FIG. 28 is a plan view showing a configuration example of the upper electrodes E2.

At the display portion DA, the red sub-pixels SP1, the green sub-pixels SP2, and the blue sub-pixels SP3 are arranged in the first direction X. A plurality of sub-pixels of the same color are arranged in the second direction Y.

Each of a plurality of upper electrodes E2 is formed in a strip shape extending in the second direction Y, and the upper electrodes E2 are arranged at intervals in the first direction X. Each of the upper electrodes E2 is arranged at the display portion DA to extend to the outside of the display portion DA. One upper electrode E2 is arranged over the sub-pixels of the same color arranged in the second direction Y.

A plurality of power supply lines FL are arranged outside the display portion DA, and overlap the upper electrodes E2, respectively, in plan view. In the contact holes CH2, the upper electrodes E2 are in contact with the power supply lines FL. A predetermined voltage is thereby applied to each of the upper electrodes E2. In other words, optimum voltages can be applied to the red sub-pixels SP1, the green sub-pixels SP2, and the blue sub-pixels SP3, respectively.

In the configuration example shown in FIG. 28, the upper electrode E2 is electrically connected to the power supply lines FL on both sides sandwiching the display portion DA, but may be connected to the power supply line FL on either of the sides.

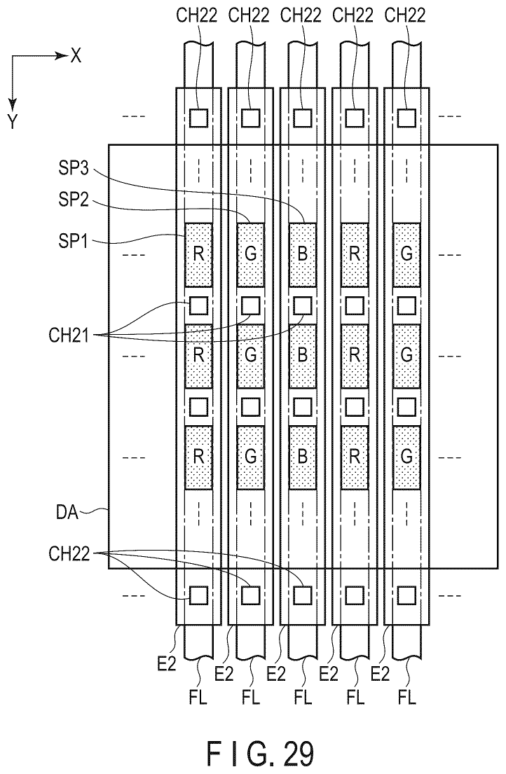

FIG. 29 is a plan view showing another configuration example of the upper electrodes E2.

The configuration example shown in FIG. 29 is different from the configuration example shown in FIG. 28 in that each of the power supply lines FL extends at the display portion DA and that the upper electrode E2 is in contact with the power supply line FL in contact holes CH21 at the display portion DA.

In addition, the upper electrode E2 extends to the outside of the display portion DA and is in contact with the power supply lines FL in the contact holes CH22. However, when the upper electrode E2 is in contact with the power supply line FL at the display portion DA, the upper electrode E2 may not be in contact with the power supply line FL outside the display portion DA.

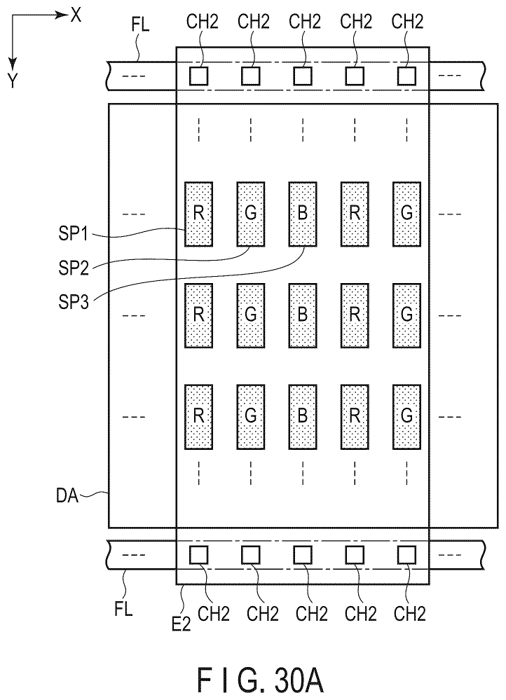

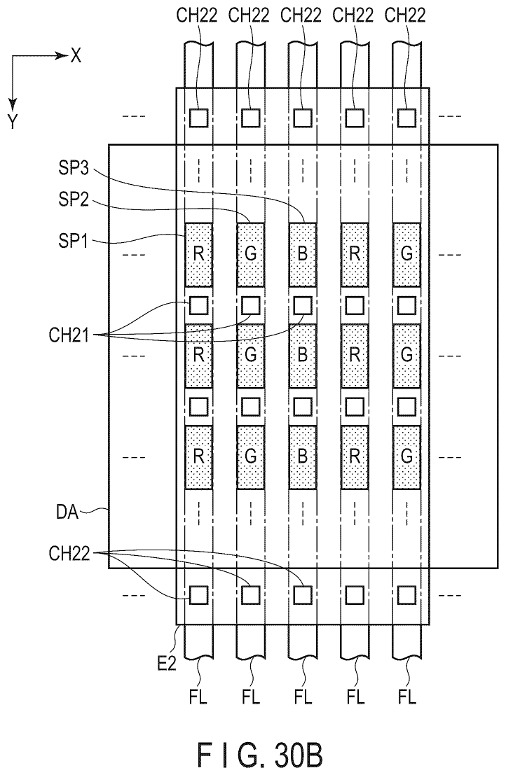

FIG. 30A is a plan view showing yet another configuration example of the upper electrode E2.

The configuration example shown in FIG. 30A is different from the configuration example shown in FIG. 28 in that the upper electrode E2 is arranged over the sub-pixels SP1, SP2, and SP3 of different colors. The upper electrode E2 extends in the second direction Y, is arranged at the display portion DA, and extends to the outside of the display portion DA.

The power supply lines FL are arranged outside the display portion DA, and overlap the upper electrode E2, in plan view. In a plurality of contact holes CH2, the upper electrode E2 is in contact with the power supply lines FL. A predetermined voltage is thereby applied to the upper electrode E2.

In the configuration example shown in FIG. 30A, the upper electrode E2 is electrically connected to the power supply lines FL on both sides sandwiching the display portion DA, but may be connected to the power supply line FL on either of the sides.

FIG. 30B is a plan view showing yet another configuration example of the upper electrodes E2.

The configuration example shown in FIG. 30B is different from the configuration example shown in FIG. 30A in that each of the power supply lines FL extends at the display portion DA and that the upper electrode E2 is in contact with the power supply line FL in contact holes CH21 at the display portion DA.

In addition, the upper electrode E2 extends to the outside of the display portion DA and is in contact with the power supply lines FL in the contact holes CH22. However, when the upper electrode E2 is in contact with the power supply line FL at the display portion DA, the upper electrode E2 may not be in contact with the power supply line FL outside the display portion DA.

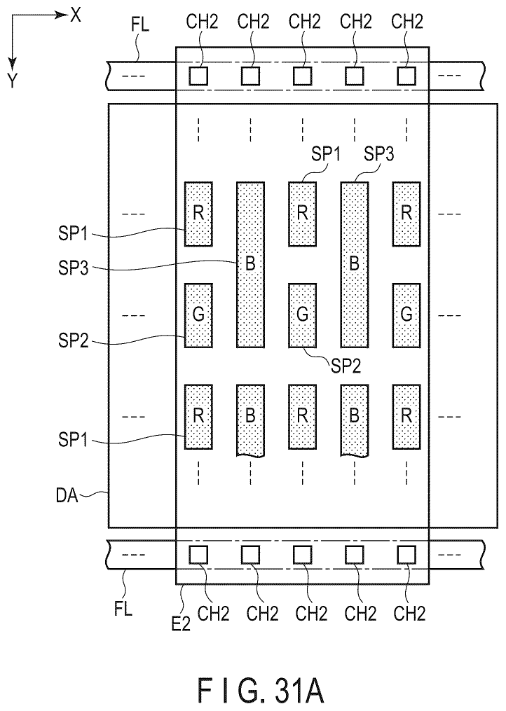

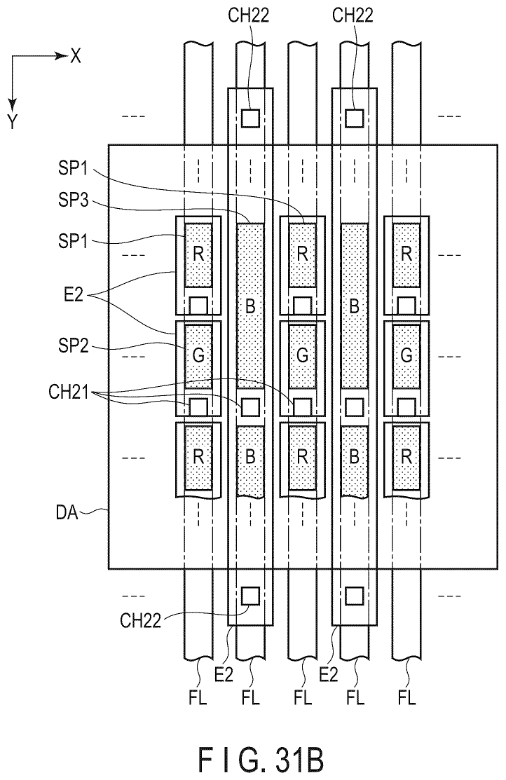

FIG. 31A is a plan view showing yet another configuration example of the upper electrode E2.

In the example shown in the drawing, area of the sub-pixel SP3 of blue (B) is larger than area of each of the sub-pixel SP1 of red (R) and the sub-pixel SP2 of green (G). In addition, as regards the length along the second direction Y, the sub-pixel SP3 is longer than the sub-pixel SP1 and the sub-pixel SP2.

At the display portion DA, the sub-pixels SP1 and the sub-pixels SP3 are alternately arranged along the first direction X. In addition, the sub-pixels SP2 and the sub-pixels SP3 are alternately arranged along the first direction X. The sub-pixels SP1 and the sub-pixels SP2 are alternately arranged along the second direction Y. The sub-pixels SP3 are arranged in the second direction Y.

In a layout of the sub-pixels, the upper electrode E2 is arranged over the sub-pixels SP1, SP2, and SP3 of different colors, similarly to the configuration example shown in FIG. 30A. In addition, the upper electrode E2 extends in the second direction Y, is arranged at the display portion DA, and extends to the outside of the display portion DA.

The power supply lines FL are arranged outside the display portion DA, and overlap the upper electrode E2, in plan view. In a plurality of contact holes CH2, the upper electrode E2 is in contact with the power supply lines FL. A predetermined voltage is thereby applied to the upper electrode E2.

FIG. 31B is a plan view showing yet another configuration example of the upper electrodes E2.

In the layout of the sub-pixels described with reference to FIG. 31A, the upper electrodes E2 formed in a strip shape are arranged at portions where a plurality of sub-pixels of the same color are arranged in the second direction Y, and the upper electrodes E2 formed in an island shape are arranged at portions where the sub-pixels of different colors are arranged in the second direction Y.

In the example shown in the drawing, the sub-pixels SP3 of blue (B) are arranged in the second direction Y. The upper electrode E2 arranged on these sub-pixels SP3 is formed in a strip shape extending in the second direction Y, is in contact with the power supply line FL in the contact hole CH21 of the display portion DA, and is in contact with the power supply line FL in the contact holes CH22 outside the display portion DA. However, the upper electrode E2 may be in contact with the power supply line FL in either of the contact holes CH21 and CH22.

The upper electrode E2 arranged at each of the sub-pixel SP1 of red (R) and the sub-pixel SP2 of green (G) is formed in an island shape, and is in contact with the power supply line FL in the contact hole CH21 of the display portion DA.

### Embodiment

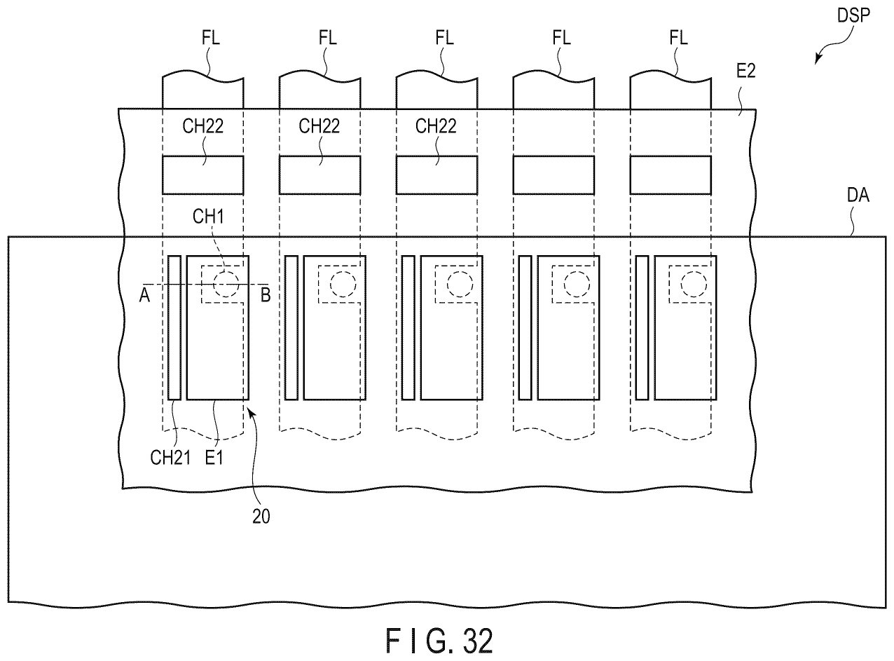

FIG. 32 is a plan view showing an embodiment.

The power supply lines FL are arranged at the display portion DA and extend to the outside of the display portion DA. At the display portion DA, the power supply lines FL do not overlap the contact holes CH1. The lower electrode E1 of each of the display element 20 overlaps the contact hole CH1 and also overlaps the power supply line FL. The contact hole CH21 is formed to be arranged with the lower electrode E1 and overlaps the power supply line FL. The contact hole CH22 overlapping the supply line FL is formed outside the display portion DA. The upper electrode E2 overlaps the lower electrode E1 and the contact hole CH21 at the display portion DA, and overlaps the contact hole CH22 outside the display portion DA.

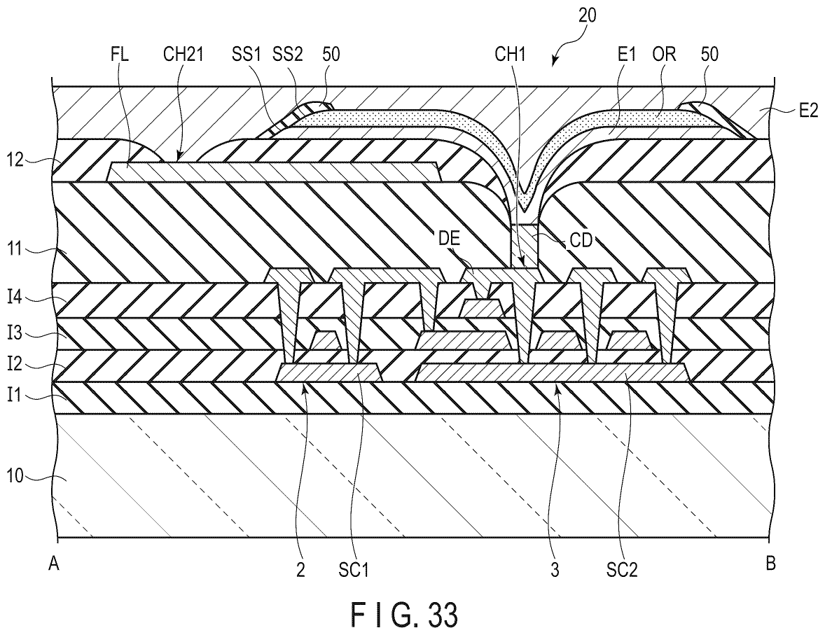

FIG. 33 is a cross-sectional view showing the display element 20 shown in FIG. 32 along line A-B.

A plurality of insulating layers I1 to 14 are arranged between the substrate 10 and the insulating layer (first insulating layer) 11. The insulating layer I1 is arranged on the substrate 10, the insulating layer 12 is arranged on the insulating layer I1, the insulating layer 13 is arranged on the insulating layer 12, the insulating layer 14 is arranged on the insulating layer 13, and the insulating layer 11 is arranged on the insulating layer 14. The insulating layers I1 to 14 are, for example, inorganic insulating layers formed of silicon nitride, silicon oxide, or the like.

A semiconductor SC1 of the pixel switch 2, and a semiconductor SC2 of the drive transistor 3 are, for example, polycrystalline silicon and are located between the insulating layer I1 and the insulating layer 12. A drain electrode DE of the drive transistor 3 is located between the insulating layer 14 and the insulating layer 11, and is in contact with the semiconductor SC2. The conductive material CD is in contact with the drain electrode DE, in the contact hole (first contact hole) CH1 formed in the insulating layer 11.

The power supply line FL is arranged on the insulating layer 11. The insulating layer (second insulating layer) 12 is arranged on the insulating layer 11, and includes the contact hoe (second contact hole) CH21 which penetrates to the power supply line FL.

The lower electrode E1 is arranged on the insulating layer 12 and is in contact with the conductive material CD in the contact hole CH1. The organic layer OR is stacked on the lower electrode E1. The coating layer 50 covers the end surface SS1 of the lower electrode E1 and the end surface SS2 of the organic layer OR. In addition, the coating layer 50 is in contact with the insulating layer 12 outside the lower electrode E1.

The upper electrode E2 covers the organic layer OR and the coating layer 50. In addition, the upper electrode E2 is in contact with the power supply line FL in the contact hole CH21 outside the display element 20.

According to such an embodiment, as described above, area contributing the display can be increased, undesired current leakage at the peripheral part of the organic layer OR and the like are suppressed, and the degradation in the performance of the display element 20 can be suppressed. In addition, a desired voltage can be applied to the upper electrode E2 of each display element 20 by the power supply line FL arranged at the display portion DA. In other words, a uniform voltage can be applied to an entire area of the display portion DA.

All of the display devices that can be implemented by a person of ordinary skill in the art through arbitrary design changes to the display devices described above as embodiments of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device comprising:
a substrate;
a switching element arranged above the substrate;
a first insulating layer arranged above the substrate and including a first contact hole penetrating to the switching element;
a conductive material filled in the first contact hole;
a lower electrode arranged above the first insulating layer and being in contact with the conductive material;
an organic layer stacked on the lower electrode and including a hole injection layer on the lower electrode, a hole transport layer on the hole injection layer, and a light emitting layer on the hole transport layer;
an upper electrode stacked on the organic layer; and
a coating layer covering an end surface of each of the lower electrode, the hole injection layer, and the hole transport layer.

2. The display device of claim 1, wherein
the organic layer further includes an electron blocking layer between the hole transport layer and the light emitting layer, and
the coating layer covers an end surface of the electron blocking layer.

3. The display device of claim 2, wherein
the coating layer covers an end surface of the light emitting layer.

4. The display device of claim 3, wherein
the organic layer further includes a hole blocking layer on the light emitting layer, and
the coating layer covers an end surface of the hole blocking layer.

5. The display device of claim 4, wherein
the organic layer further includes an electron transport layer on the hole blocking layer, and
the coating layer covers an end surface of the electron transport layer.

6. The display device of claim 5, wherein
the organic layer further includes an electron injection layer on the electron transport layer, and
the coating layer covers an end surface of the electron injection layer.

7. The display device of claim 1, wherein
the organic layer further includes an electron blocking layer between the hole transport layer and the light emitting layer, and a hole blocking layer between the light emitting layer and the upper electrode, and
the coating layer is at least one of the electron blocking layer and the hole blocking layer.

8. A display device comprising:
a substrate;
a switching element arranged above the substrate;
a first insulating layer arranged above the substrate and including a first contact hole penetrating to the switching element;
a conductive material filled in the first contact hole;
a lower electrode arranged above the first insulating layer and being in contact with the conductive material;
an organic layer including a light emitting layer, and stacked on the lower electrode;
an upper electrode stacked on the organic layer; and
a coating layer covering an end surface of the lower electrode.

9. The display device of claim 8, further comprising:
a sealing layer, wherein
the sealing layer covers the upper electrode and the coating layer and is in contact with the first insulating layer.

10. The display device of claim 8, further comprising:
a sealing layer, wherein
the upper electrode covers the coating layer and is in contact with the first insulating layer, and
the sealing layer is stacked on the upper electrode.

11. A display device comprising:
a substrate;
a switching element arranged above the substrate;
a first insulating layer arranged above the substrate and including a first contact hole penetrating to the switching element;
a conductive material filled in the first contact hole;
a lower electrode arranged above the first insulating layer and being in contact with the conductive material;
an organic layer including a light emitting layer, stacked on the lower electrode, and covering an end surface of the lower electrode; and
an upper electrode stacked on the organic layer and covering an end surface of the organic layer.

12. The display device of claim 11, further comprising:
a sealing layer, wherein
the sealing layer covers the upper electrode and is in contact with the first insulating layer.

13. The display device of claim 11, further comprising:
a sealing layer, wherein
the upper electrode is in contact with the first insulating layer, and
the sealing layer is stacked on the upper electrode.

14. The display device of claim 1, wherein
a boundary surface between the conductive material and the lower electrode is located under an upper surface of the first insulating layer.

15. The display device of claim 1, wherein
a boundary surface between the conductive material and the lower electrode is located above an upper surface of the first insulating layer.

16. The display device of claim 1, further comprising:
a power supply line arranged on the first insulating layer; and
a second insulating layer including a second contact hole penetrating to the power supply line, wherein
the upper electrode is in contact with the power supply line in the second contact hole.

17. The display device of claim 1, further comprising:
a sealing layer, wherein
the sealing layer covers the upper electrode and the coating layer and is in contact with the first insulating layer.

18. The display device of claim 1, further comprising:
a sealing layer, wherein
the upper electrode covers the coating layer and is in contact with the first insulating layer, and
the sealing layer is stacked on the upper electrode.
